(19) United States
(12) Patent Application Publication
(10) Pub. No.: US 2024/0313150 A1
(43) Pub. Date: Sep. 19, 2024

(54) PROCESS FOR PRODUCING LIGHT-EMITTING DIODES

(71) Applicant: COMMISSARIAT A L'ENERGIE ATOMIQUE ET AUX ENERGIES ALTERNATIVES, Paris (FR)

(72) Inventors: Bruno DAUDIN, Grenoble Cedex 09 (FR); Bruno GAYRAL, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/575,478

(22) PCT Filed: Jun. 27, 2022
(86) PCT No.: PCT/FR2022/051268

§ 371 Date: Dec. 29, 2023

(30) Foreign Application Priority Data
Jul. 2, 2021 (FR) FR2107203

(51) Int. Cl. H01L 33/00

(52) U.S. Cl. CPC H01L 33/0075

(57) ABSTRACT

A process for producing light-emitting diodes includes producing a first segment made of inorganic semiconductor doped with a first conductivity type; producing, on a first region of the first segment and through a mask, a first emitting segment made of inorganic semiconductor; moving the mask; producing, on a second region of the first segment, a second emitting segment made of inorganic semiconductor; and producing, at least on the first and second emitting segments, a segment made of inorganic semiconductor doped with a second conductivity type. The chemical compositions of the first and second emitting segments are different from each other and such that their bandgaps are narrower than or equal to those of the segments made of doped inorganic semiconductor.

### TECHNICAL FIELD

The invention relates to the field of producing light-emitting diodes, or LEDs. The invention relates in particular to the production of a display device with LEDs, and more particularly the production of a microdisplay device with LEDs.

### PRIOR ART

Display devices, in particular the microdisplay devices used for example for smartphone screens, comprise a set of pixels. When the display device corresponds to a colour screen, each pixel can comprise at least three LEDs or micro-LEDs, each forming a sub-pixel, each locally emitting one of the three following elementary or primary colours: red, green and blue. In this case these are called RGB pixels.

Such a display device is generally produced by assembling the various LEDs on a support, for a large number of pixels. This assembly step is complicated to carry out without defects. This is particularly critical during the production of small high-resolution display devices. Just one of these defects produces a “dead” pixel not emitting the desired colour, which is unacceptable for a display device intended for sale.

The LEDs used for the production of a display device generally comprise organic materials and are called OLEDs (Organic Light-Emitting Diodes). The emission of the three colours red, green and blue is obtained by producing OLEDs from different organic materials. For each colour, structures having large surface areas are manufactured, then cut into small elements each corresponding to an LED, before the final assembly. This solution is costly and has limited reliability.

Moreover, the luminance of the display devices containing OLEDs is limited, which is particularly bothersome in the case of pixels having very small dimensions used in high-resolution display devices.

This luminance can be improved by producing LEDs from inorganic semiconductors. For example, the semiconductor materials containing nitride allow to manufacture very efficient LEDs for producing a light emission of blue colour and, to a lesser extent, of green colour. In particular, it is possible to produce GaN/InGaN heterostructures forming quantum wells and in which the quantity of indium incorporated is adjusted in order to modify the wavelength of emission of the LEDs. However, these semiconductor materials containing nitride do not allow to obtain, with this same technology, LEDs emitting a light of red colour that are as efficient as those emitting in the ranges of wavelengths corresponding to the colours blue and green. It is therefore necessary, to form red subpixels, to use another family of materials, namely that of the phosphides (GaP/GaInP). This technical complication for producing LEDs as well as the difficulties related to the assembly without defects of a large number of LEDs currently limit the performance and the size of the display devices that can be produced with this technique.

It is also known to produce monochromatic LEDs by implantation of ions of rare earths in nanowires of GaN or of AlN. However, this solution is also confronted with the problems related to the assembly of the subpixels thus produced and the defects that result therefrom.

The document by S. Ichikawa et al., “Eu-doped GaN and InGaN monolithically stacked full-color LEDs with a wide color gamut”, 2021 Appl. Phys. Express 14 031008, proposes a production of LEDs in the form of a monolithic vertical stack comprising three stacked active layers each emitting in one of the primary colours. One of these active layers comprises atoms of europium and is used to produce a light emission of red colour. The two other active layers comprise quantum wells of InGaN, the chemical composition of which is adjusted to emit in the blue for one of these two layers, and in the green for the other of these two layers. The solution proposed in this document solves the assembly problem disclosed above, but it requires multiple technological steps to be able to create the electric contacts of each of the LEDs at various levels of the stack.

### DISCLOSURE OF THE INVENTION

One goal of the present invention is to propose a method for producing light-emitting diodes, or LEDs, not having the disadvantages of the methods of the prior art described above.

For this, a method for producing light-emitting diodes is proposed, comprising at least:
producing at least one portion of inorganic semiconductor doped according to a first type of conductivity;
producing, on the portion of inorganic semiconductor doped according to the first type of conductivity and through at least one mask comprising at least one opening disposed facing at least one first region of the portion of inorganic semiconductor doped according to the first type of conductivity, at least one first emissive portion of inorganic semiconductor;
moving the mask such that the opening is disposed facing at least one second region, distinct from the first region, of the portion of inorganic semiconductor doped according to the first type of conductivity;
producing, on the portion of inorganic semiconductor doped according to the first type of conductivity and through the mask, at least one second emissive portion of inorganic semiconductor;
producing, at least on the first and second emissive portions, at least one portion of inorganic semiconductor doped according to a second type of conductivity opposite to the first type of conductivity,
wherein the chemical compositions of the first and second emissive portions are different from each other and such that their forbidden band energies are less than or equal to those of the portions of doped inorganic semiconductor.

This method proposes producing at least two LEDs, wherein the first emissive portion and the parts of the portions of doped semiconductor located on either side of this first emissive portion form a first LED. This first LED is defined geometrically (shape and dimensions), in a plane parallel to main faces (faces having the largest surface areas and through which the first opening passes) of the mask, by the opening of the mask which defines and locates this first emissive portion.

Likewise, the second emissive portion and the parts of the portions of doped semiconductor located on either side of this second emissive portion form a second LED. This second LED is defined geometrically (shape and dimensions), in a plane parallel to main faces (faces having the largest surface areas and through which the second opening passes) of the mask, by the opening of the mask which was moved with respect to the production of the first emissive portion and which defines and locates this second emissive portion.

This method thus proposes a technical solution for the production, for example over a significant surface area, of several LEDs, without assembly of these LEDs or complex steps for being able to create electric contacts on these LEDs.

This method allows to produce various LEDs emitting in different ranges of wavelengths, in the same level, by horizontal integration while avoiding the disadvantages of vertical integration and the associated technological complications.

This method proposes locally producing LEDs capable of emitting lights of different wavelengths of the visible range that depend on the chemical compositions of the emissive portions produced. The LEDs are thus successively produced in-situ in the same semiconductor stack, thus avoiding the later implementation of an assembly of LEDs.

Moreover, this method does not use organic materials and potentially allows to obtain a luminance better than that obtained for OLEDs.

Throughout the document, the term “LED” is used to designate an LED or a micro-LED, without distinction of its dimensions.

The forbidden band energies of the portions of doped inorganic semiconductor can be different, and in this case, the forbidden band energy of one of the emissive portions can be less than or equal to that of the portion of doped inorganic material having the lowest forbidden band energy.

The difference between the chemical compositions of the various emissive portions produced can be obtained by incorporating ions of rare earths of a different nature in the various emissive portions and/or by producing the various emissive portions with chemical compounds comprising atoms of various natures (for example AlGaN, InGaN, etc.) and/or the proportions of which are different (for example InₓGa₍₁₋ₓ₎N and In_{y}Ga_{(1-Y)}N with X having a different value than Y).

Each of the incorporations of ions of rare earths that can be implemented in this method corresponds to an incorporation of at least one type of ions of rare earths. In other words, each of the incorporations can correspond to an incorporation of ions of rare earths of one or more different types, and optionally of atoms not corresponding to ions of rare earths. For example, to optimise the chemical process of light emission of the ions of rare earths for a given colour, it is possible to produce in the same emissive portion a co-doping of optionally different rare earths, accompanied by atoms not corresponding to ions of rare earths. For example, for an emission in the red, a co-doping of europium and of oxygen can be carried out.

The incorporation of ions of rare earths in the sense of the invention corresponds to the use of atomic fluxes comprising rare earths in the frame, for example of the MBE type (“Molecular Beam Epitaxy”), for producing the emissive portions, and for example by epitaxy of these emissive portions.

Each of the light-emitting diodes produced can comprise a single emissive portion disposed between the portions of doped inorganic semiconductor, or a stack of several emissive portions separated from each other by one or more barrier layers, the forbidden band energy of which is greater than that of the emissive portions, the stack being disposed between the portions of doped inorganic semiconductor.

Moreover, each of the steps for producing emissive portions implemented can form one or more emissive portions, according to the number of openings of the mask used.

The movement of the mask corresponds to a relative movement of the mask with respect to the portion of inorganic semiconductor doped according to the first type of conductivity on which the emissive portions are produced, that is to say that it is possible to move the mask and/or the semiconductor portion.

First rare earth ions can be incorporated into the inorganic semiconductor of the first emissive portion and/or second rare earth ions can be incorporated into the inorganic semiconductor of the second emissive portion.

According to a specific exemplary embodiment, the first rare earth ions can be incorporated into the inorganic semiconductor of the first emissive portion and the second rare earth ions, of a different nature than the first rare earth ions, can be incorporated into the inorganic semiconductor of the second emissive portion.

The method can further comprise, after the production of the second emissive portion and before the production of the portion of inorganic semiconductor doped according to the second type of conductivity:
moving the mask such that the opening is disposed facing at least one third region, distinct from the first and second regions, of the portion of inorganic semiconductor doped according to the first type of conductivity, then
producing, on the portion of inorganic semiconductor doped according to the first type of conductivity and through the mask, at least one third emissive portion of inorganic semiconductor, the chemical composition of which is different than those of the first and second emissive portions and such that its forbidden band energy is less than or equal to those of the portions of doped inorganic semiconductor.

According to a specific exemplary embodiment, third ions of rare earths of a nature different than that of the first and second rare earth ions can be incorporated into the third emissive portion, and/or the third emissive portion can comprise a chemical compound comprising atoms of different natures or the proportions of which are different than the chemical compounds of the first and second emissive portions.

Advantageously, the chemical compositions of the first, second and third emissive portions can be chosen such that the first, second and third emissive portions are each capable of emitting wavelengths corresponding to one of the colours red, green and blue. In a specific exemplary embodiment, ions of rare earths incorporated into the first, second and third emissive portions can be chosen from europium (allowing the emission of red light), terbium and/or erbium (allowing the emission of green light), and thulium (allowing the emission of blue light) ions. It is also possible to use praseodymium (allowing the emission of red light) and/or holmium (allowing the emission of green light) and/or cerium (allowing the emission of blue light) ions.

The method can further comprise, after the production of the third emissive portion and before the production of the portion of inorganic semiconductor doped according to the second type of conductivity:
moving the mask such that the opening is disposed facing at least one fourth region, distinct from the first, second and third regions, of the portion of inorganic semiconductor doped according to the first type of conductivity, then
producing, on the portion of inorganic semiconductor doped according to the first type of conductivity and through the mask, at least one fourth emissive portion of inorganic semiconductor, the chemical composition of which is similar to that of one of the first, second and third emissive portions.

According to a specific exemplary embodiment, fourth ions of rare earths of a nature similar to that of the first or second or third rare earth ions can be incorporated into the fourth emissive portion, and/or the fourth emissive portion can comprise a chemical compound comprising atoms of similar natures and the proportions of which are similar to the chemical compounds of one of the first, second and third emissive portions.

In this case, the first, second, third and fourth emissive portions can advantageously be produced such that they are arranged by forming a matrix.

The mask used for the production of each of the emissive portions corresponds to a hard mask.

The steps for producing the portions of doped inorganic semiconductor and the emissive portions can each comprise the implementation of an epitaxy or of a deposition.

Advantageously, the portions of doped inorganic semiconductor and the emissive portions can comprise chemical compounds comprising atoms of nitrogen as well as atoms of aluminium and/or of gallium and/or of indium. Thus, the III-N semiconductors produced in this method can correspond to GaN or AlN or InN and their ternary or quaternary alloys (AlGaN, InGaN, InAlN, AlGaInN). The use of such semiconductors containing nitride is particularly advantageous since:
the efficacy of energy transfer to the rare earth ions that can emit light is even higher since the value of the gap of the semiconductor is high, which is the case of the semiconductors containing nitride, and in particular of GaN and of AlN and of the alloys containing AlGaN;
by producing an emissive portion capable of emitting in the red by incorporation of Eu, it is possible, with the family of semiconductors containing nitride and in particular via InGaN, to manufacture other emissive portions emitting in the blue and the green.

In an advantageous exemplary embodiment, the portions of doped inorganic semiconductor and the emissive portions can comprise AlN.

Advantageously, the method can further comprise, before the production of the portion of inorganic semiconductor doped according to the first type of conductivity, a production of at least one portion, called base portion, of semiconductor doped according to the first type of conductivity on a substrate, the portion of inorganic semiconductor doped according to the first type of conductivity being then produced on the base portion. Such a base portion allows in this case to initiate a growth of the first portion of inorganic semiconductor doped according to the first type of conductivity on any type of substrate, for example semiconductor, amorphous, or metal.

Advantageously, the base portion comprises GaN or is composed of GaN.

The portions of inorganic semiconductor and the emissive portions can be produced in the form of nanowires or planar layers. The production of the semiconductor portions in the form of nanowires is advantageous since it allows to avoid a possible lateral diffusion of the atomic species sent during the production of the LEDs. It is therefore possible to obtain a total separation of the various colours emitted by the various emissive portions produced.

In this case, the method can further comprise, when the portions of inorganic semiconductor and the emissive portions are produced in the form of nanowires, a step of depositing an electric insulant material between the nanowires, implemented after the production of the portion of inorganic semiconductor doped according to the second type of conductivity. This allows in particular to passivate the lateral sides of the nanowires.

The first type of conductivity can correspond to the n type and the second type of conductivity can correspond to the p type.

The method can be such that:
the portion of inorganic semiconductor doped according to the second type of conductivity is doped by atoms of magnesium and/or of indium, and/or
the portion of inorganic semiconductor doped according to the first type of conductivity is doped by atoms of silicon and/or of germanium.

The electron transitions involved in a light emission of a semiconductor into which ions of rare earths have been incorporated correspond to those occurring for deep electrons belonging to the electron layer 4f of the rare earth ions. The screening of this layer by the electrons of the outer layers makes the emission very stable and independent of the nature of the surrounding material which can be crystalline or amorphous, semiconductor or insulating. When these ions of rare earths are introduced into a semiconductor, the electron transitions occurring in the electron layer 4f can be excited by the passage of a current, the return to the ground state being thus accompanied by a light emission. The efficacy of the excitation and of the coupling on the one hand and the lifetime of the excited luminescence on the other hand are sensitive to the value of the gap of the semiconductor into which the ions of rare earths are incorporated. The greater the gap, the more the total efficacy increases.

Advantageously, in the method described here, the doping by atoms of magnesium and of indium of the p-doped semiconductor allows to use semiconductors with large gaps such as for example AlN, which allows to obtain regions of light emission having a very good luminous efficacy.

The presence of indium in the inorganic semiconductor doped according to the second type of conductivity allows to incorporate, with respect to this same semiconductor not comprising any indium, a greater number of doping atoms of magnesium because the atomic concentration of magnesium obtained is proportional to the quantity of indium present in the semiconductor. Thus, the level of p-type doping that can for example be obtained in the semiconductor of the second portion is in this case greater and allows to obtain a greater injection of current and a better distribution of the current lines. For example, the presence of indium in AlN or in AlGaN allows to increase the solubility of the magnesium in these materials by a factor equal to approximately 10, and thus increases the level of doping that can be obtained in this semiconductor.

The possibility of incorporating a greater number of atoms of magnesium when the semiconductor comprises indium is unexpected since these two types of atoms cause, when they are introduced separately in particular into AlN, a compressive stress. There is therefore a priori no reason for their simultaneous introduction to be favourable in terms of accumulated elastic energy since the addition of the indium does not contribute to the relaxing of the elastic stress caused by the addition of the magnesium.

The atomic concentration of magnesium in the inorganic semiconductor doped according to the second type of conductivity can be between 10²⁰ at/cm³ and 10²¹ at/cm³, or greater than 10²⁰ at/cm³, and/or the atomic concentration of silicon and/or of germanium in the inorganic semiconductor doped according to the first type of conductivity can be between 10¹⁹ at/cm³ and 10²⁰ at/cm³. Such an atomic concentration of magnesium is for example obtained when the ratio between the atomic concentration of magnesium and the atomic concentration of indium is between 1 and 20, or between 1 and 50, or even between 1 and 100, and preferably approximately 10. This configuration allows to obtain a good level of p-type doping of the semiconductor via, for example, the significant lowering of the effective ionisation energy of the magnesium at such levels of doping, and thus a good injection of current in the LED via the electric conduction of the second portion which is close or similar to that of a metal electrode.

A method for producing a display device, comprising the implementation of the method for producing light-emitting diodes as described above, is also proposed.

This method can advantageously be implemented to produce a display device with RGB pixels, that is to say each comprising at least three subpixels emitting wavelengths corresponding to the colours red, green and blue. But in general, this method can be implemented to produce display devices provided with pixels each comprising at least two subpixels emitting different wavelengths which do not necessarily correspond to the RGB pixels.

This method does not have the disadvantages related to the assembly of several subpixels produced separately to each form pixels of the display device.

This method can be implemented to produce a display device having a large surface area. The later assembly of several of these devices can allow to increase by an arbitrarily large factor the size of the final device to reach that of a computer or television screen or for wall display.

Throughout the document, the term “on” is used without distinguishing the orientation in space of the element to which this term refers. For example, in the feature “on a face of a portion”, this face of the portion is not necessarily oriented upwards but can correspond to a face oriented according to any direction. Moreover, the arrangement of a first element on a second element must be understood as being able to correspond to the arrangement of the first element directly against the second element, without any intermediate element between the first and second elements, or as being able to correspond to the arrangement of the first element on the second element with one or more intermediate elements disposed between the first and second elements.

### BRIEF DESCRIPTION OF THE DRAWINGS

The present invention will be better understood upon reading the description of exemplary embodiments given for purely informational and in no way limiting purposes while referring to the appended drawings in which:

FIGS. 1 to 7 show the steps implemented during a method for producing light-emitting diodes, object of the present invention, according to a first embodiment;

FIG. 8 shows light-emitting diodes obtained by the implementation of a method for producing light-emitting diodes, object of the present invention, according to an alternative of the first embodiment;

FIG. 9 shows a light-emitting diode obtained by the implementation of a method for producing light-emitting diodes, object of the present invention, according to a second embodiment;

FIG. 10 shows a display device produced by implementing a method forming the object of the present invention.

Identical, similar or equivalent parts of the various figures described below carry the same numerical references so as to facilitate the passage from one figure to the other.

The various parts shown in the figures are not necessarily shown according to a uniform scale, to make the figures more readable.

The various possibilities (alternatives and embodiments) must be understood as not being exclusive of each other and can be combined with each other.

### DETAILED DISCLOSURE OF SPECIFIC EMBODIMENTS

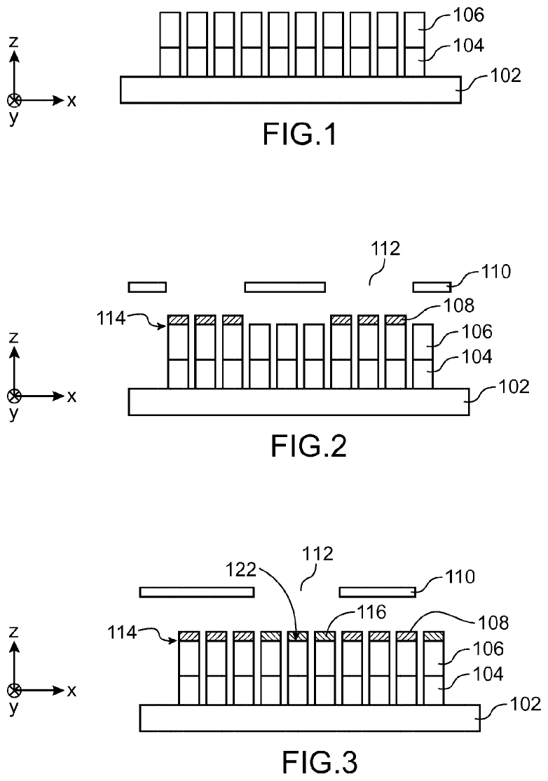

A method for producing LEDs 100 according to a first embodiment is described below in relation to FIGS. 1 to 7.

In the exemplary embodiment described here, the LEDs 100 are produced in the form of nanowires created by epitaxy on a substrate 102 comprising for example semiconductor such as silicon, or sapphire or another material.

Advantageously, the epitaxy steps implemented here to form the nanowires correspond to steps of plasma-assisted molecular beam epitaxy or PA-MBE. Alternatively, these steps can correspond to steps of deposition, for example like metalorganic chemical vapour deposition or MOCVD, or of metalorganic vapour phase epitaxy or MOVPE, or of pulsed laser deposition or PLD.

To form these nanowires, in a first step, base portions 104 of semiconductor, advantageously of GaN, doped according to a first type of conductivity are produced by growth in the form of nanowires. The production of these base portions 104 is optional. These base portions 104 allow to facilitate the later growth of the other portions of materials of the LEDs 100.

In this exemplary embodiment, the first type of conductivity corresponds to the n type.

Portions of inorganic semiconductor 106 doped according to the first type of conductivity, here of n-doped AlN, are then produced by growth on the portions 104 (see FIG. 1). For example, the n doping can be obtained by introducing atoms of silicon and/or of germanium into the material of the portions 106. The concentration of dopants in the semiconductor of the portions 106 is for example between 10¹⁷ at/cm³ and 10²⁰ at/cm³ and advantageously 10¹⁹ at/cm³ and 10²⁰ at/cm³. The dimension of each of the portions 106 parallel to the direction of growth of the nanowires (dimension parallel to the axis Z in FIGS. 1 to 7) is for example equal to 500 nm, or more generally between 100 and 1000 nm.

First emissive portions 108 of inorganic semiconductor, here of AlN, are then produced by growth through a mask 110 comprising openings 112 disposed facing first regions 114 of the portions 106 (see FIG. 2). These first emissive portions 108 are intended to be part of first LEDs producing a light emission in a first range of wavelengths. For this, during the growth of the first emissive portions 108, first ions of rare earths are incorporated into the semiconductor of the first emissive portions 108. For example, when the first emissive portions 108 are intended to emit a light of red colour, the first ions of rare earths incorporated can correspond to europium ions.

After having produced the first emissive portions 108, the mask 110 is moved such that the openings 112 are disposed facing second regions 112, distinct from the first regions 114, of the portions 106.

Second emissive portions 116 of inorganic semiconductor, here of AlN, are then produced by growth through the mask 110, facing the openings 112 (see FIG. 3). These second emissive portions 116 are intended to be part of second LEDs producing a light emission in a second range of wavelengths. For this, the second emissive portions 116 are produced such that their chemical composition is different than that of the first emissive portions 108. In the first embodiment, during the growth of the second emissive portions 116, second ions of rare earths, of a different nature than the first ions of rare earths, are incorporated into the semiconductor of the second emissive portions 116 in order to obtain this difference in chemical composition between the first and second emissive portions 108, 116. For example, when the second emissive portions 116 are intended to emit a light of green colour, the second ions of rare earths incorporated can correspond to terbium and/or erbium ions.

In the exemplary embodiment described here, the mask 110 is once again moved such that the openings 112 are disposed facing third regions, distinct from the first and second regions 114, 122, of the portions 106.

Third emissive portions 124 of inorganic semiconductor, here of AlN, are then produced by growth through the mask 110, facing the openings 112. These third emissive portions 124 are intended to be part of third LEDs producing a light emission in a third range of wavelengths. For this, the third emissive portions 124 are produced such that their chemical composition is different than that of the first and second emissive portions 108, 116. In the first embodiment, during the growth of the third emissive portions 124, third ions of rare earths, of a different nature than the first and second ions of rare earths, are incorporated into the semiconductor of the third emissive portions 124 in order to obtain this difference in chemical composition between the third emissive portions 124 on the one hand and the first and second emissive portions 108, 116 on the other hand. For example, when the third emissive portions 124 are intended to emit a light of blue colour, the third ions of rare earths incorporated can correspond to thulium ions.

In the exemplary embodiment described here, the mask 110 is once again moved such that the openings 112 are disposed facing fourth regions, distinct from the first, second and third regions of the portions 106.

Fourth emissive portions 126 of inorganic semiconductor, here of AlN, are then produced by growth through the mask 110, facing the openings 112. These fourth emissive portions 126 are intended to be part of fourth LEDs producing a light emission in a range of wavelengths similar to one of the first, second or third ranges of wavelengths. For this, the fourth emissive portions 126 are produced such that their chemical composition is similar to that of the first emissive portions 108 or to that of the second emissive portions 116 or to that of the third emissive portions 124. In the first embodiment, during the growth of the fourth emissive portions 126, fourth ions of rare earths of a nature similar to that of the first, second or third ions of rare earths are incorporated into the semiconductor of the fourth emissive portions 126 in order to obtain this similarity in chemical composition between the fourth emissive portions 126 and the first or second or third emissive portions 108, 116, 124. It is for example advantageous for the fourth emissive portions 126 to be intended to emit a light of red colour, like the first emissive portions 108, because this colour corresponds to that for which the light emission is the least efficient, and the fourth ions of rare earths incorporated can correspond in this case to europium ions.

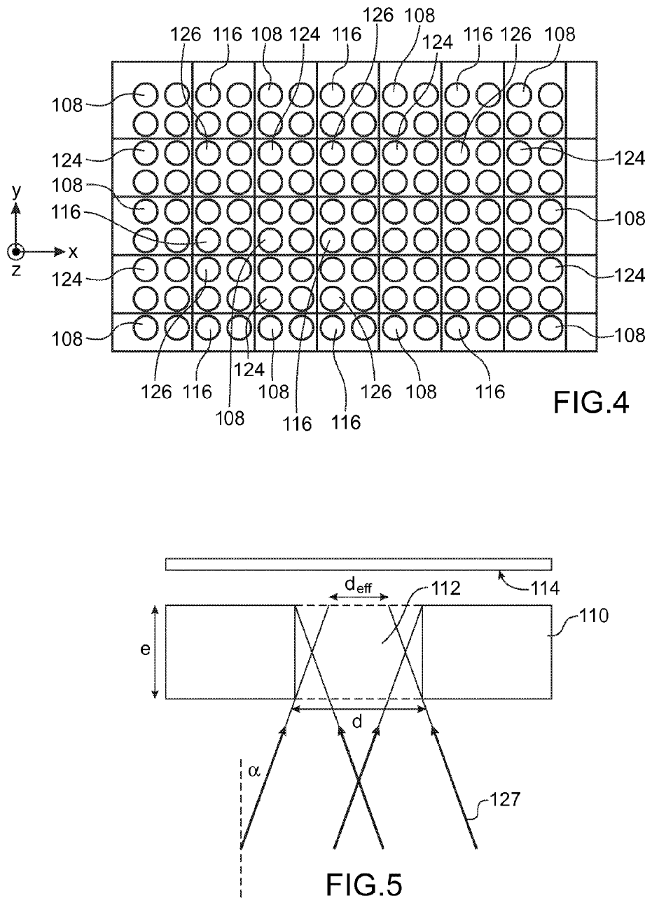

FIG. 4 schematically shows, viewed from the top, an example of distribution of the emissive portions 108, 116, 124 and 126 produced. In this example, these emissive portions 108, 116, 124 and 126 are arranged by forming a matrix, that is to say in rows and columns.

The dimension of each of the emissive portions 108, 116, 124 and 126 parallel to the direction of growth of the nanowires (parallel to the axis Z in FIGS. 1 to 7) is for example between 5 nm and 50 nm.

In a piece of equipment for molecular beam epitaxy, the atomic fluxes produced by the cells used form an angle α with respect to the normal to the surface on which the epitaxy is carried out. The value of this angle α depends in particular on the piece of equipment and on the cells used, and is for example between 25° and 30°. Given that the substrate 102 is in rotation during the growth, the value of a diameter d_{eff} of a region of the surface on which the epitaxy is carried out and where the surface density of epitaxied material is the highest depends on a thickness e of the mask used, on a dimension d of the opening through which the epitaxy is carried out (for example the diameter in the case of an opening having a circular cross-section or the dimension of one of the sides in the case of an opening having a square or rectangular cross-section), and on the angle α according to the formula:

$${d}_{eff} = d - 2. e . tan ( α )$$

This configuration is schematically shown in FIG. 5. In this figure, the atomic fluxes produced during the epitaxy carry the reference 127.

For example, for α=25°, d=5 μm and e=1 μm, the value of d_{eff} is equal to approximately 4 μm.

Around this region having a diameter d_{eff}, another region in the shape of a ring having a width equal to e·tan(α) is also formed by the epitaxy. The surface density of ions of rare earths obtained in this other region is equal to half of that deposited in the region having a diameter d_{eff}. The speed of growth in this other region is also reduced by half with respect to that in the central region having a diameter d_{eff}. Thus, the density of ions of rare earths is constant over the entire zone of diameter d.

The optimisation of the size and of the morphology of the LEDs produced thus depends in particular on a judicious choice of the parameters e and d of the masks used.

Moreover, for example, each opening can have, in a plane parallel to the surface on which the epitaxy is carried out, a cross-section having a rectangular or square shape, for example having dimensions between 2×2 μm² and 5×5 μm². When the dimensions of one of the openings are equal to 2×2 μm², the number of portions of nanowires located facing such an opening is for example equal to 400.

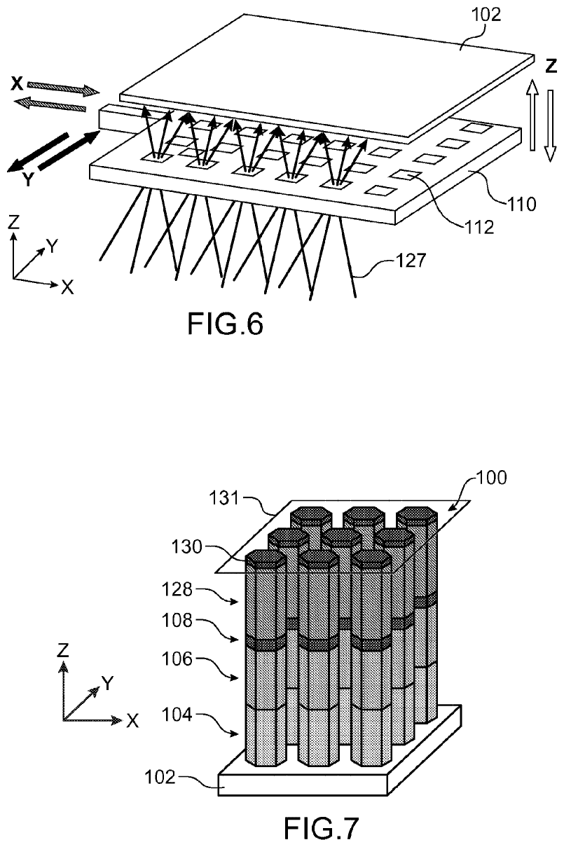

FIG. 6 illustrates an example of an operating mode for the production of the emissive portions 108, 116, 124 and 126 through the mask 110 used for the production of these emissive portions. In this figure, atomic fluxes 127 are sent through the mask 110 which is rigidly connected to a device allowing to move it according to the axis Z (to move it closer to the desired distance from the deposition surface) and according to the axes X and Y (to vary the position of the zone exposed to the atomic beams at which the growth is carried out).

The mask can be produced ex situ, that is to say outside of the frame where the growth is carried out. This mask is for example produced from a wafer of silicon on which SiN is deposited in order to limit the contamination of the wafer via the low rate of bonding of the atomic fluxes on the SiN, and through which the openings are produced for example by lithography. This lithography can also form ribs in order to confer a good mechanical rigidity onto the mask.

Portions 128 of inorganic semiconductor doped according to a second type of conductivity, here of p-doped AlN, are then produced by growth on the portions 108, 116, 124 and 126. Like for the production of the portions 106, no mask is used for the growth of these portions 128.

The p-type doping is here advantageously obtained by incorporating atoms of magnesium and of indium into the portions 128. Advantageously, the atomic concentration of magnesium in the semiconductor of these portions 128 is between 10¹⁷ at/cm³ and 10²¹ at/cm³, and advantageously between 10²⁰ at/cm³ and 10²¹ at/cm³.

For the growth of the semiconductor of the portions 128 by MBE, fluxes of aluminium, of active nitrogen, of indium and optionally of gallium are sent onto the growth surface which corresponds to the upper surface of the emissive portions 108, 116, 124, 126. A flux of magnesium is also sent in order for the semiconductor produced to be p-doped by the atoms of magnesium. The values of these fluxes, that is to say the quantity of atoms of each of these chemical elements sent, are chosen according to the composition desired for the semiconductor of the portions 128 and in particular in such a way that the atomic concentration of indium is between 0 and 1% and preferably equal to 0.1%. In the presence of this flux of indium, the atomic concentration of magnesium in the semiconductor of the portions 128 is proportional to the quantity of indium incorporated into this semiconductor and is for example between 10¹⁷ at/cm³ and 10²¹ at/cm³, and advantageously between 10²⁰ at/cm³ and 10²¹ at/cm³, or an atomic concentration of magnesium between 0.1% and 1%.

During a production of the portion 128 by growth by MOCVD, the elements used for the growth of the semiconductor are organometallic precursors, for example trimethylaluminium or triethylaluminium used as a source of aluminium, ammonia used as a source of nitrogen, trimethylindium or triethylindium used as a source of indium, and optionally trimethylgallium or triethylgallium used as a source of gallium. The atoms of magnesium are obtained by a suitable precursor, for example a solution of magnesocene or Mg(Cp)2. The concentrations of indium and of magnesium that can be obtained by MOCVD can be similar to those obtained by MBE.

The dimension according to the axis Z of each of the portions 128 is advantageously very short so as to optimise the injection of current into the pixels 101 produced, and for example between 50 nm and 300 nm, and advantageously between 50 nm and 100 nm.

Advantageously, the structure of nanowires produced is completed by producing by growth a short portion 130 of strongly p-doped GaN, which allows to facilitate the creation of electric contact with the LEDs produced. The thickness (dimension according to the axis Z) of the portion 130 is for example between 20 nm and 30 nm.

The diameter of each nanowire formed by the portions 104, 106, 108 (or one of the portions 116, 124, 126) and 128 is for example between 100 nm and 150 nm. The period, or rate of repetition, with which the nanowires are produced, which corresponds to the distance between the centres of two neighbouring nanowires, is for example between 150 nm and 300 nm. According to a specific exemplary embodiment, the value of the period can be equal to double that of the diameter of one of the nanowires.

According to a specific exemplary embodiment, the portions 128 and 130 produced can be located on the central parts of the emissive portions 108, 116, 124, 126 having diameters d_{eff}, to avoid a possible difference in intensity of emission that would be caused by the differences in properties between these central parts and the rest of the emissive portions 108, 116, 124, 126.

An electric contact 131 can then be deposited on the structure produced. This electric contact 131 comprises an electrically conductive and transparent material, for example indium tin oxide (ITO).

This step of producing the electric contact 131 can be preceded by a step of passivation and of planarisation, corresponding for example to a deposition of electrically insulating material between the nanowires. This deposition is for example of the ALD type (atomic layer deposition). The material deposited is for example aluminium oxide, or SiO₂, or any other electrically insulating material adapted for such a deposition. The deposition of this insulating material allows to passivate the lateral surfaces of the nanowires and limit the non-radiative recombinations of carriers on the surface defects which are detrimental to the efficacy of the LEDs 100. This deposition of insulating material also allows to give a certain mechanical resistance to all of the nanowires. A step of polishing can then be implemented to form a flat surface facilitating the deposition of the electric contact 131.

FIG. 7 schematically shows one of the LEDs 100 obtained after the implementation of the steps described above.

In the exemplary embodiment described above, the materials produced by growth correspond to AlN or GaN. More generally, each of the various portions 104, 106, 108, 116, 124, 126, 128 and 130 can comprise compounds including atoms of nitrogen as well as atoms of aluminium and/or of gallium and/or of indium. For example, according to one alternative, the portions 104 and 106 of each nanowire can correspond to a single portion of material, for example n-doped GaN or n-doped AlGaN.

Alternatively to the first embodiment described above, it is possible to not produce the portions 104, and to produce the portions 106 directly on the substrate 102.

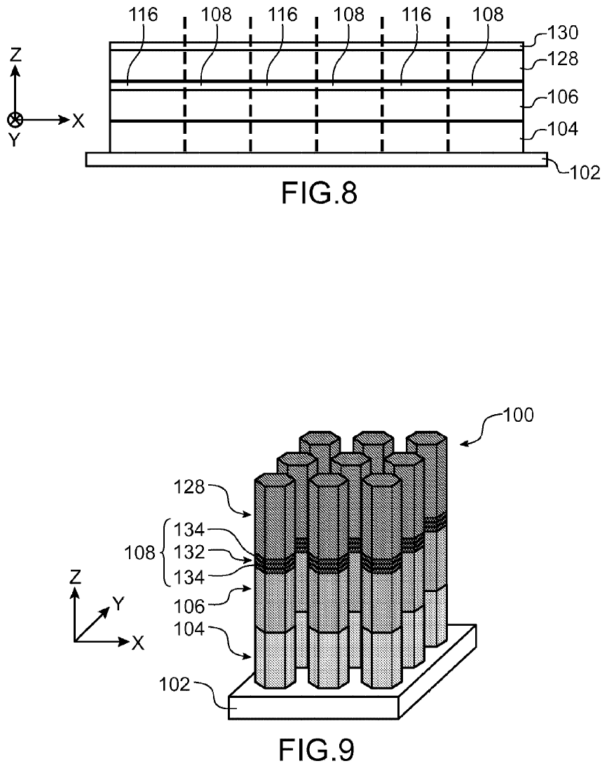

Alternatively to the first embodiment described above in which the various portions of materials are produced in the form of nanowires, it is possible for these various portions to be produced in the form of layers of materials successively deposited on the substrate 102. Unlike the nanowires that form distinct vertical structures next to each other on the substrate 102, the layers deposited on the substrate 102 are continuous between two neighbouring LEDs 100. FIG. 8 schematically shows a cross-sectional view of the structure obtained according to this alternative. The techniques implemented to form such layers are advantageously depositions of the MOCVD or PLD type.

In the first embodiment described above, the regions of light emission of the LEDs 100 are obtained via the incorporation of ions of rare earths in the emissive portions, leading to obtaining emissive portions having different chemical compositions.

In a second embodiment, the regions of light emission of the LEDs 100 can be obtained by producing, between the portions 106 and 128, structures with one or more quantum wells, or MQW (Multiple Quantum Well).

FIG. 9 schematically shows an exemplary embodiment of an LED 100 according to this second embodiment. In this exemplary embodiment, an emissive portion is formed, in each nanowire, by a quantum well of InGaN disposed between two barrier layers of GaN 134. Like in the first embodiment, the quantum wells forming the emissive portions are produced through the mask 110 in order to successively produce, on the various regions of the portions 106, emissive portions capable of emitting different wavelengths. Contrary to the first embodiment in which the wavelengths emitted by the active regions depend on the types of rare earth ions incorporated, the wavelengths emitted by the various portion depend, in this second embodiment, on the nature and/or the atomic proportions of the chemical compounds of the emissive portions, for example the concentration of indium (which can be between 1% and 10%, and advantageously between 1% and 5%) in the case of quantum wells comprising InGaN. Like in the first embodiment, the chemical compositions of the wells can be chosen so as to form emissive portions capable of emitting wavelengths corresponding to the colour red, others capable of emitting wavelengths corresponding to the colour green, and others capable of emitting wavelengths corresponding to the colour blue.

In the example of FIG. 9, each nanowire produced comprises a single emissive portion disposed between two barrier layers 134. Alternatively, it is possible for the barrier layers between which the emissive portion is disposed to be formed by the portions of doped inorganic semiconductor 106 and 128.

Moreover, it is also possible that each nanowire a stack of several emissive portions separated from each other by one or more barrier layers, for example similar to the barrier layers 134, the forbidden band energy of which is greater than that of the emissive portions, this stack being disposed between the portions of doped inorganic semiconductor.

The various alternatives described above for the first embodiment can be applied to the second embodiment.

Moreover, according to an alternative of the second embodiment, it is possible for one or more emissive portions 108, 116, 124, 126 to be formed by a quantum well or a stack of several superimposed quantum wells into which ions of rare earths are incorporated. Such an alternative is advantageous since in this case, the emissive portions (for example made of InGaN) located between the barrier layers allow to determine zones of confinement of the carriers to maximise their presence near the ions of rare earths, and thus maximise the efficacy of excitation of the ions of rare earths.

According to other alternatives, it is possible to have some of the emissive portions incorporating ions of rare earths and/or one or more other emissive portions not incorporating ions of rare earths.

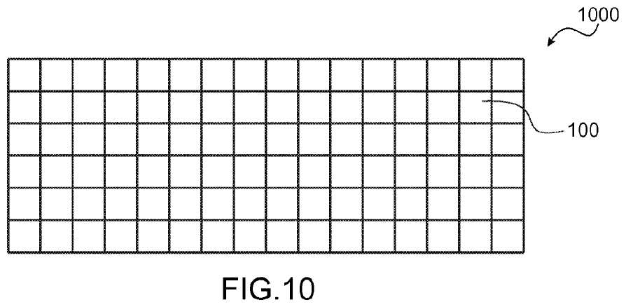

For all the embodiments and alternatives described above, a display device 1000, corresponding for example to a screen, can be obtained by producing pixels of this device 1000 with the LEDs 100 described above. For example, each pixel of such a device 1000 can be formed by four LEDs 100 arranged by forming a 2×2 matrix. Such a device 1000 is schematically shown in FIG. 10.

1. A method for producing light-emitting diodes, comprising:
producing at least one portion of inorganic semiconductor doped according to a first type of conductivity;
producing, on the at least one portion of inorganic semiconductor doped according to the first type of conductivity and through at least one mask comprising at least one opening disposed facing at least one first region of the at least one portion of inorganic semiconductor doped according to the first type of conductivity, at least one first emissive portion of inorganic semiconductor;
moving the at least one mask such that the at least one opening is disposed facing at least one second region, distinct from the at least one first region, of the at least one portion of inorganic semiconductor doped according to the first type of conductivity;
producing, on the at least one portion of inorganic semiconductor doped according to the first type of conductivity and through the at least one mask, at least one second emissive portion of inorganic semiconductor; and
producing, at least on the at least one first and the at least one second emissive portions, at least one portion of inorganic semiconductor doped according to a second type of conductivity opposite to the first type of conductivity,
wherein chemical compositions of the at least one first emissive portion and the at least one second emissive portion are different from each other and such that their forbidden band energies are less than or equal to those of the at least one portion of inorganic semiconductor doped according to the first type of conductivity and the at least one portion of inorganic semiconductor doped according to the second type of conductivity.

2. The method according to claim 1, wherein first rare earth ions are incorporated into the inorganic semiconductor of the at least one first emissive portion and/or wherein second rare earth ions are incorporated into the inorganic semiconductor of the at least one second emissive portion.

3. The method according to claim 2, wherein the first rare earth ions are incorporated into the inorganic semiconductor of the at least one first emissive portion and the second rare earth ions, of a different nature than the first rare earth ions, are incorporated into the inorganic semiconductor of the at least one second emissive portion.

4. The method according to claim 1, further comprising, after producing the at least one second emissive portion and before producing the at least one portion of inorganic semiconductor doped according to the second type of conductivity:
moving the at least one mask such that the at least one opening is disposed facing at least one third region, distinct from the at least one first region and the at least one second region, of the at least one portion of inorganic semiconductor doped according to the first type of conductivity, then
producing, on the at least one portion of inorganic semiconductor doped according to the first type of conductivity and through the at least one mask, at least one third emissive portion of inorganic semiconductor, a chemical composition of which is different than those of the first and second emissive portions and such that a forbidden band energy of the at least one third emissive portion is less than or equal to those of the at least one portion of inorganic semiconductor doped according to the first type of conductivity and the at least one portion of inorganic semiconductor doped according to the second type of conductivity.

5. The method according to claim 4, wherein the chemical compositions of the at least one first, at least one second and at least one third emissive portions are chosen such that the at least one first, second and third emissive portions are each capable of emitting wavelengths corresponding to one of the colours red, green and blue.

6. The method according to claim 4, further comprising, after producing the at least one third emissive portion and before producing the at least one portion of inorganic semiconductor doped according to the second type of conductivity:
moving the at least one mask such that the at least one opening is disposed facing at least one fourth region, distinct from the at least one first, at least one second and at least one third regions, of the at least one portion of inorganic semiconductor doped according to the first type of conductivity, then
producing, on the at least one portion of inorganic semiconductor doped according to the first type of conductivity and through the at least one mask, at least one fourth emissive portion of inorganic semiconductor, a chemical composition of which is similar to that of one of the at least one first, at least one second and at least one third emissive portions.

7. The method according to claim 6, wherein the at least one portion of inorganic semiconductor doped according to the first type of conductivity, the at least one portion of inorganic semiconductor doped according to the second type of conductivity and the at least one first, at least one second, at least one third and at least one fourth emissive portions comprise chemical compounds comprising atoms of nitrogen as well as atoms of aluminium and/or of gallium and/or of indium.

8. The method according to claim 1, further comprising, before producing the at least one portion of inorganic semiconductor doped according to the first type of conductivity, producing at least one base portion of semiconductor, doped according to the first type of conductivity on a substrate, the at least one portion of inorganic semiconductor doped according to the first type of conductivity being then produced on the at least one base portion.

9. The method according to claim 8, wherein the base portion comprises GaN.

10. The method according to claim 6, wherein the at least one portion of inorganic semiconductor doped according to the first type of conductivity and the at least one portion of inorganic semiconductor doped according to the second type of conductivity and the at least one first, at least one second, at least one third and at least one fourth emissive portions are produced in a form of nanowires or of planar layers.

11. The method according to claim 10, further comprising, when the at least one portion of inorganic semiconductor doped according to the first type of conductivity, the at least one portion of inorganic semiconductor doped according to the second type of conductivity and the at least one first, at least one second, at least one third and at least one fourth emissive portions are produced in the form of nanowires, depositing an electric insulant material between the nanowires, implemented after producing the at least one portion of inorganic semiconductor doped according to the second type of conductivity.

12. The method according to claim 1, wherein the first type of conductivity corresponds to the n type and the second type of conductivity corresponds to the p type.

13. The method according to claim 1, wherein:
the at least one portion of inorganic semiconductor doped according to the second type of conductivity is doped by atoms of magnesium and/or of indium, and/or
the at least one portion of inorganic semiconductor doped according to the first type of conductivity is doped by atoms of silicon and/or of germanium.

14. A method for producing a display device, comprising implementing the method for producing light-emitting diodes according to claim 1.
